(19) United States
(12) Patent Application Publication
(10) Pub. No.: US 2025/0338037 A1
(43) Pub. Date: Oct. 30, 2025

(54) BINARY PIXEL SENSOR CIRCUIT ASSEMBLY

(71) Applicant: University of Tennessee Research Foundation, Knoxville, TN (US)

(72) Inventors: Ahmedullah Aziz, Knoxville, TN (US); Mazharul Islam, Knoxville, TN (US); Rahatul Islam Udoy, Knoxville, TN (US)

(21) Appl. No.: 19/194,606

(22) Filed: Apr. 30, 2025

Related U.S. Application Data
(60) Provisional application No. 63/640,595, filed on Apr. 30, 2024.

(51) Int. Cl. H04N 25/772; H10F 39/00

(52) U.S. Cl. CPC H04N 25/772; H10F 39/8037

(57) ABSTRACT

A binary pixel sensor circuit assembly for employment in image sensors utilized for computer vision, medical imaging, document analysis, and artificial intelligence (AI) applications, among many other possible applications of use. The binary pixel sensor circuit assembly, per an implementation, includes a pixel array having a multitude of individual pixels. Each of the individual pixels has an in-pixel binarization module residing therein. The binarization modules each have a first transistor and a second transistor. The first transistor is in the form of a hybrid phase transition field-effect transistor (HyperFET) that has a phase transition material (PTM). The phase transition material transitions to and from an insulating state and a metal state amid effecting an output (e.g., 1 or 0) of the binary pixel sensor circuit assembly in different illumination levels.

### CROSS-REFERENCE TO RELATED APPLICATION

This application claims the benefit of U.S. Provisional Patent Application No. 63/640,595, with a filing date of Apr. 30, 2024, the contents of which are hereby incorporated by reference in their entirety.

### TECHNICAL FIELD

The present disclosure relates generally to image sensors and, more particularly, to binary pixel sensor circuits and binarization modules employed in image sensors.

### BACKGROUND

Image sensors are semiconductor devices that convert optical images into digital signals. A binary pixel sensor is a type of image sensor that executes an image binarization process. In general, image binarization converts color or grayscale images into binary images in which individual pixels are black (e.g., output 0) or white (e.g., output 1) based on a predetermined threshold. Image binarization is often employed in applications in which the acquisition and processing of full-scale color and/or grayscale images are deemed unnecessary. The process can be an important precursor to image-processing tasks. Preference for binary images typically centers around computational efficiency, data storage requirements, and processing speed.

Applications of use include computer vision, medical imaging, document analysis, and artificial intelligence (AI), among many other possibilities. Within computer vision applications, for instance, image binarization has proved critical for image segmentation, object recognition, and edge detection tasks. Still further, in real-time applications in which rapid decision-making is paramount—such as in many AI applications—binary image adoption promises enhanced resource utilization and computational workflows, among other expected advancements. Fields in which image binarization can be useful include, but are not limited to, automotive, aerospace, medical, robotics, civilian, and military fields.

Past binary pixel sensors and binarization modules commonly employed the use of comparators. Due to the relatively large size of the comparators, these past binarization modules were typically located outside of an associated pixel array. Indeed, a single binarization module and comparator was positioned at the end of a particular column of pixels, and shared by all of the pixels in that column. But shortcomings in this arrangement have since been observed. For one, the signals traversing the pixel array are analog until they are received by the comparators and hence are susceptible to noise. Further, because pixels in a particular column rely on a single and shared comparator for binarization, the speed of execution suffers.

### SUMMARY

In an embodiment, a binary pixel sensor circuit assembly may include a pixel array. The pixel array may include a multitude of pixels. Some or more of the pixels have a binarization module that resides within the pixels. The binarization module may include a first transistor and a second transistor that are electrically coupled with each other. The first transistor is in the form of a hybrid phase transition field-effect transistor (HyperFET). The HyperFET has a phase transition material (PTM) at a source terminal thereof.

In an embodiment, a binary pixel sensor circuit assembly may include a multitude of pixels. Some or more of the pixels have a binarization module. The binarization module may include a first transistor and a second transistor. The first transistor is in the form of a hybrid phase transition field-effect transistor (HyperFET). The HyperFET has a phase transition material (PTM). During operation of the binary pixel sensor circuit assembly and at a lower illumination level the PTM of the HyperFET remains in an insulating state and an output of the binarization module remains unchanged. Further, during operation of the binary pixel sensor circuit assembly and at a higher illumination level the PTM of the HyperFET transitions from an insulating state to a metal state and the output of the binarization module changes. Yet further, during operation of the binary pixel sensor circuit assembly, a pulse width of a threshold gate pulse signal that activates the second transistor is variable, while a reference voltage remains substantially constant.

In an embodiment, a binary pixel sensor circuit assembly may include a pixel array. The pixel array may include a multitude of pixels. All of the pixels each have a in-pixel binarization module. The in-pixel binarization module of each of the pixels may include a first transistor and a second transistor that are electrically coupled with each other. The first transistor is in the form of a hybrid phase transition field-effect transistor (HyperFET). The HyperFET has a phase transition material (PTM) at a source terminal thereof. During operation of the binary pixel sensor circuit assembly and at a lower illumination level the PTM of the HyperFET remains in an insulating state and an output of the in-pixel binarization module remains unchanged. Further, during operation of the binary pixel sensor circuit assembly and at a higher illumination level the PTM of the HyperFET transitions from an insulating state to a metal state and the output of the in-pixel binarization module changes. Yet further, during operation of the binary pixel sensor circuit assembly, a pulse width of a threshold gate pulse signal that activates the second transistor is variable, while a reference voltage remains substantially constant, and a threshold time period of the threshold gate pulse signal is variable with respect to a photodiode voltage of the binary pixel sensor circuit assembly, while the reference voltage remains substantially constant.

Further scope of applicability of the present disclosure will become apparent from the detailed description given hereinafter. But it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given below and the accompanying drawings, which are given by way of illustration only, and do not limit the present disclosure, and wherein:

FIG. 1 is a schematic depiction of an embodiment of an image sensor having a pixel array;

FIG. 2(a) is a schematic diagram of a past 3-transistor (3-T) pixel circuit;

FIG. 2(b) is a graph of a timing diagram of the past 3-T pixel circuit, with time plotted on an x-axis and voltage plotted on a y-axis;

FIG. 3(a) is a schematic depiction of an embodiment of a structure of a phase transition material (PTM);

FIG. 3(b) is a schematic depiction of an embodiment of a structure of a hybrid phase transition field-effect transistor (HyperFET) having a phase transition material (PTM) at a source terminal thereof;

FIG. 3(c) is a schematic diagram of a circuit symbol used for the HyperFET;

FIG. 3(d) is a graph presenting current (I) and voltage (V) characteristics of a phase transition material (PTM), with voltage plotted on an x-axis and current plotted on a y-axis;

FIG. 3(e) is a graph presenting current (I) and voltage (V) characteristics of the HyperFET, with voltage plotted on an x-axis and current plotted on a y-axis;

FIG. 4 is a table of simulation parameters of an embodiment of a phase transition material (PTM);

FIG. 5 is a schematic depiction of an embodiment of a pixel array with pixels having in-pixel binarization modules;

FIG. 6 is a schematic diagram of an embodiment of a circuit of a binary pixel sensor circuit assembly having a hybrid phase transition field-effect transistor (HyperFET) with a phase transition material (PTM);

FIG. 7(a) is a schematic diagram of an embodiment of a reset phase that occurs amid operation of the binary pixel sensor circuit assembly;

FIG. 7(b) is a schematic diagram of an embodiment of a light integration phase that occurs amid operation of the binary pixel sensor circuit assembly at a low illumination level;

FIG. 7(c) is a schematic diagram of an embodiment of a sensing phase that occurs amid operation of the binary pixel sensor circuit assembly at a low illumination level;

FIG. 7(d) is a schematic diagram of an embodiment of a latching phase that occurs amid operation of the binary pixel sensor circuit assembly at a low illumination level;

FIG. 7(e) is a schematic diagram of an embodiment of a light integration phase that occurs amid operation of the binary pixel sensor circuit assembly at a high illumination level;

FIG. 7(f) is a schematic diagram of an embodiment of a sensing phase that occurs amid operation of the binary pixel sensor circuit assembly at a high illumination level;

FIG. 7(g) is a schematic diagram of an embodiment of a latching phase that occurs amid operation of the binary pixel sensor circuit assembly at a high illumination level;

FIG. 8(a) is a graph depicting a waveshape of the binary pixel sensor circuit assembly having the HyperFET with the PTM for a low illumination level, with time on an x-axis and voltage on a y-axis;

FIG. 8(b) is a graph depicting a waveshape of the binary pixel sensor circuit assembly having the HyperFET with the PTM for a low illumination level, with time on an x-axis and voltage on a y-axis;

FIG. 8(c) is a graph depicting a waveshape of the binary pixel sensor circuit assembly having the HyperFET with the PTM for a low illumination level, with time on an x-axis and voltage on a y-axis;

FIG. 8(d) is a graph depicting a waveshape of the binary pixel sensor circuit assembly having the HyperFET with the PTM for a low illumination level, with time on an x-axis and voltage on a y-axis;

FIG. 8(e) is a graph depicting a waveshape of the binary pixel sensor circuit assembly having the HyperFET with the PTM for a low illumination level, with time on an x-axis and resistance on a y-axis;

FIG. 8(f) is a graph depicting a waveshape of the binary pixel sensor circuit assembly having the HyperFET with the PTM for a high illumination level, with time on an x-axis and voltage on a y-axis;

FIG. 8(g) is a graph depicting a waveshape of the binary pixel sensor circuit assembly having the HyperFET with the PTM for a high illumination level, with time on an x-axis and voltage on a y-axis;

FIG. 8(h) is a graph depicting a waveshape of the binary pixel sensor circuit assembly having the HyperFET with the PTM for a high illumination level, with time on an x-axis and voltage on a y-axis;

FIG. 8(i) is a graph depicting a waveshape of the binary pixel sensor circuit assembly having the HyperFET with the PTM for a high illumination level, with time on an x-axis and voltage on a y-axis;

FIG. 8(j) is a graph depicting a waveshape of the binary pixel sensor circuit assembly having the HyperFET with the PTM for a high illumination level, with time on an x-axis and resistance on a y-axis;

FIG. 8(k) is an enlarged view of the waveshape of FIG. 8(g) at a thresholding time period Tₜₕ;

FIG. 8(l) is an enlarged view of the waveshape of FIG. 8(h) at a thresholding time period Tₜₕ;

FIG. 8(m) is an enlarged view of the waveshape of FIG. 8(i) at a thresholding time period Tₜₕ;

FIG. 8(n) is an enlarged view of the waveshape of FIG. 8(j) at a thresholding time period Tₜₕ;

FIG. 9(a) is a graph depicting a waveshape of a photodiode voltage (V_{PD}) and a fixed reference voltage (V_{REF}) of the binary pixel sensor circuit assembly having the HyperFET with the PTM for an embodiment of a variable thresholding technique and mechanism;

FIG. 9(b) is a graph depicting a waveshape of a threshold gate pulse signal (TH_{EN}) of the binary pixel sensor circuit assembly having the HyperFET with the PTM for the variable thresholding technique and mechanism, illustrating that the threshold gate pulse signal is lowered at two thresholding enabling time periods Tₜₕ₁ and Tₜₕ₂ (i.e., at time Tₜₕ₁, V_{PD}<V_{REF}; and at time Tₜₕ₂, V_{PD}>V_{REF});

FIG. 9(c) is a graph depicting a waveshape of different outputs (i.e., OUT₁ and OUT₂) at the thresholding enabling time periods Tₜₕ₁ and Tₜₕ₂ of the binary pixel sensor circuit assembly having the HyperFET with the PTM for the variable thresholding technique and mechanism;

FIG. 9(d) is a graph depicting a waveshape showing that the PTM switches for the thresholding enabling time period Tₜₕ₁ and showing that the PTM does not switch for the thresholding enabling time period Tₜₕ₂ of the binary pixel sensor circuit assembly having the HyperFET with the PTM for the variable thresholding technique and mechanism;

FIG. 10 is a schematic stick diagram of an embodiment of a first layer (e.g., lower layer) of the binary pixel sensor circuit assembly having the HyperFET with the PTM for an area estimation utilizing fourteen nanometer (14 nm) fin field-effect transistors (FinFET); and

FIG. 11 is a schematic depiction of an embodiment of an image sensor exhibiting a stacked configuration with a binary pixel sensor circuit assembly situated at a first layer and a photodiode assembly situated at a second layer.

### DETAILED DESCRIPTION

Referring generally to the drawings, an embodiment of a binary pixel sensor circuit assembly 10 is depicted in the figures and described herein. In general, the binary pixel sensor circuit assembly 10 executes an image binarization process amid its use. Unlike past binary pixel sensors and past binarization modules, the binary pixel sensor circuit assembly 10 is equipped with a hybrid phase transition field-effect transistor (HyperFET) 12 that has a phase transition material (PTM) 14 in its design and construction, serving to enable an in-pixel binarization module 16 for each of the individual pixels 18 in the larger assembly and installation. Comparators located outside of pixels and shared by columns of pixels—largely conventional in past arrangements—are dispensed with in the binary pixel sensor circuit assembly 10, and hence the associated shortcomings observed in the past arrangements are circumvented. Moreover, according to certain embodiments, the binary pixel sensor circuit assembly 10 employs a variable thresholding technique and mechanism for effectively discerning scene features across diverse lighting conditions. Compared to the past arrangements, the binary pixel sensor circuit assembly 10 is simpler and more compact in design and construction, exhibits an increased processing speed and a decreased power consumption, exhibits enhanced computational efficiencies, and has a lower area; still, other advancements are possible. Overall, a more effective and efficient binary pixel sensor circuit assembly is furnished. Applications of use include computer vision, medical imaging, document analysis, and artificial intelligence (AI), among many other possibilities. And fields in which image binarization is useful include, but are not limited to, automotive, aerospace, medical, robotics, civilian, and military fields. Still, a particular embodiment of the binary pixel sensor circuit assembly may exhibit only one, all, or a combination of, the advancements set forth herein, none of the advancements, or yet other advancements unmentioned.

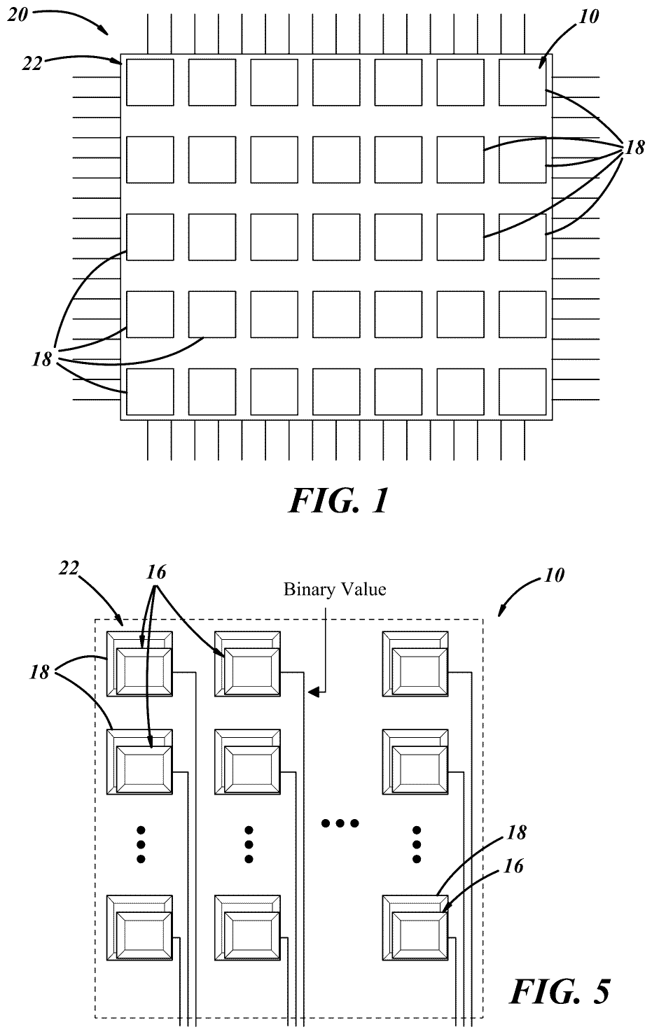

With reference now to FIG. 1, an embodiment of an image sensor and chip 20 is presented. A pixel array 22 of the image sensor and chip 20 is made-up of a multitude of the individual pixels 18 arranged in horizontal rows and vertical columns relative to one another; still, other arrangements of pixels are possible. Each of the pixels 18 can be equipped with an individual and dedicated in-pixel binarization module 16 (see FIG. 5). The phrase “in-pixel” is intended to mean that the design, construction, and components of the binarization module 16 are incorporated and located within each of the pixels 18. In other words, the in-pixel binarization module 16 resides physically within a boundary of its respective pixel 18, and hence the accompanying binarization process is carried out within that pixel 18. A pixel-level processing circuit is thereby furnished. All of the pixels 18 in the pixel array 22 can have the in-pixel binarization module 16, per an embodiment, or only some of the pixels 18 in the pixel array 22 can have the in-pixel binarization module 16. Locating the binarization module 16 in-pixel has been shown to partly or more contribute to one or more of the following advancements: i) simpler and more compact design and construction, ii) increased processing speed, iii) decreased power consumption, iv) enhanced computational efficiencies, and v) lower area; still, other advancements can arise from the in-pixel location.

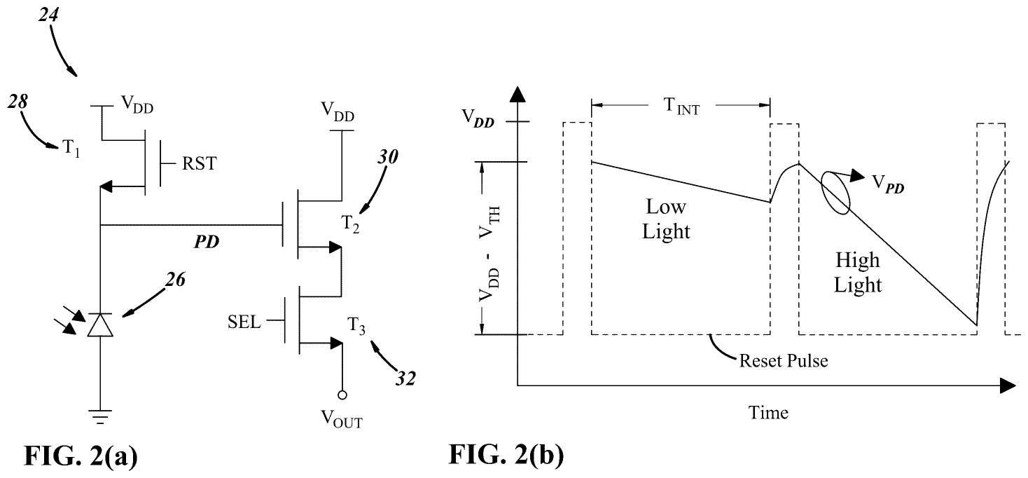

Referring now to FIG. 2(a), a past 3-transistor (3-T) pixel circuit 24 is presented for demonstrative and explanatory purposes. The 3-T pixel circuit 24 has been the building block of past pixel arrays. The 3-T pixel circuit 24 in this example includes a reverse-biased photodetector 26 and three transistors 28 (T₁), 30 (T₂), and 32 (T₃). The transistor 28 is referred to as a reset transistor (RST); the transistor 30 is referred to as a source follower; and the transistor 32 is referred to as a row selector transistor (SEL). FIG. 2(b) presents a timing diagram for the 3-T pixel circuit 24. Operation of the 3-T pixel circuit 24 is initiated by turning on and activating the reset transistor 28, which serves to reset a photodetector (PD) node voltage (V_{PD}) to V_{DD}−V_{TH,T1}, when a soft reset is employed. Here, V_{TH,T1} is representative of a threshold voltage of the reset transistor 28. This node can be fully charged to V_{DD} by using a hard reset or using a p-channel metal-oxide-semiconductor (PMOS) as the reset transistor 28. After the reset phase, an integration period is initiated upon deactivating the reset transistor 28. A voltage drop at the PD node with respect to time is induced by a photocurrent resulting from generated photoelectrons in the photodetector 26, as specified by equation (1):

$$\frac{dv}{dt} = \frac{{I}_{PD}}{{C}_{PD}}$$

where I_{PD} denotes the photocurrent and C_{PD} is the intrinsic capacitance of the photodiode. As demonstrated by the diagram of FIG. 2(b), higher illumination leads to higher I_{PD} which causes faster declining of V_{PD}. The source follower transistor 30 is used to transfer the PD node signal while preserving the accumulated charge undisturbed. And the row selector transistor 32 serves to select the pixel for reading out from the pixel array. An output signal (V_{OUT}) of the 3-T pixel circuit 24 is analog, which suffers from I²R loss and is susceptible to noise while traversing the pixel array.

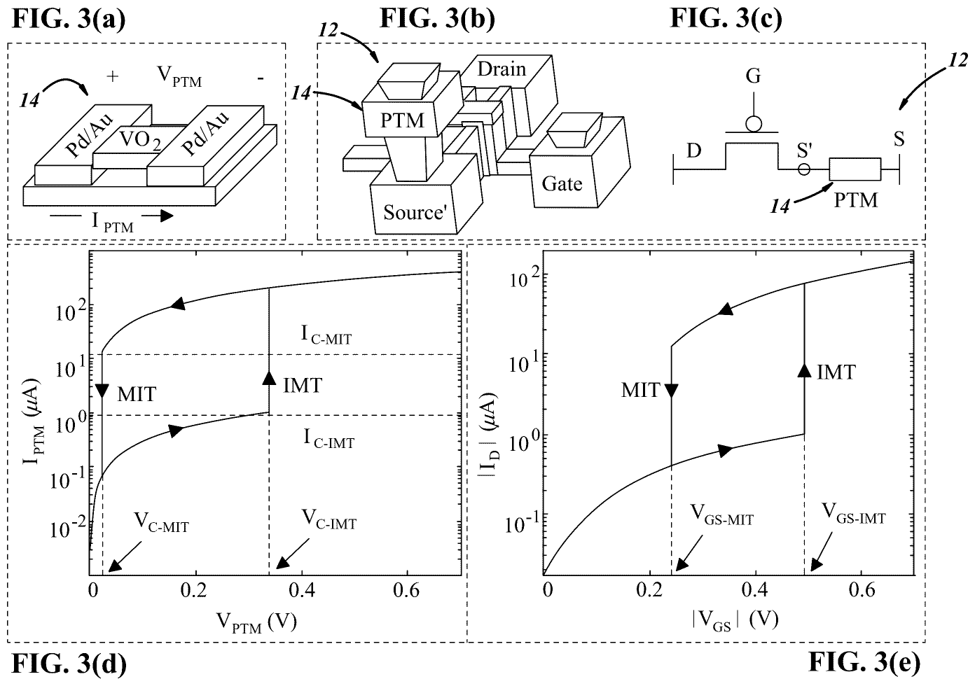

As set forth, the HyperFET 12 has the PTM 14 in its design and construction. Phase transition materials, in general, are a class of materials characterized by abrupt changes in resistivity, and can undergo transitions that are triggered by various stimuli. The PTM 14 of the HyperFET 12 is triggered by electrical stimuli. In this embodiment, the PTM 14 is composed of a vanadium dioxide (VO₂) based material, but could be composed of other materials in other embodiments. An embodiment of the PTM 14 and its structure is presented in FIG. 3(a). At lower voltages, the PTM 14 typically remains in a high-resistance or insulating state. But upon application of a higher voltage greater than a critical value (V_{C-IMT}), an insulator-to-metal transition (IMT) takes place (see the graph of FIG. 3(d)), and the corresponding current density is called J_{C-IMT}. In its insulating state, the PTM 14 exhibits a resistivity (ρ_{INS}) that is orders of magnitude greater than that of its metallic or metal state (ρ_{M}). Conversely, when the voltage is reduced to a sufficiently low level (V_{C-MIT}), the PTM 14 undergoes a metal-to-insulator transition (MIT), and the corresponding current density is called J_{C-MIT}.

In an embodiment, the PTM 14 is integrated into a source terminal of a field-effect transistor (FET), thereby constituting the HyperFET 12. In essence, the HyperFET 12 combines the behavior of a FET with the abrupt switching property of a phase transition material (i.e., the PTM 14). At lower |V_{GS}|, the FET is off and the PTM 14 remains in the high resistance state (HRS), effectively behaving like an extremely high resistance at the source terminal, and thereby reducing an off-current (I_{OFF}) of the associated transistor (see FIG. 3(e)). When the |V_{GS}| crosses a critical voltage (|V_{GS-IMT}|), the PTM 14 undergoes an IMT transition, eventually acting as a very low resistance at the source terminal. Conversely, when the |V_{GS}| is reduced to a sufficiently low level (|V_{GS-MIT}|), the PTM 14 undergoes a metal-to-insulator transition (MIT) and again goes to the HRS.

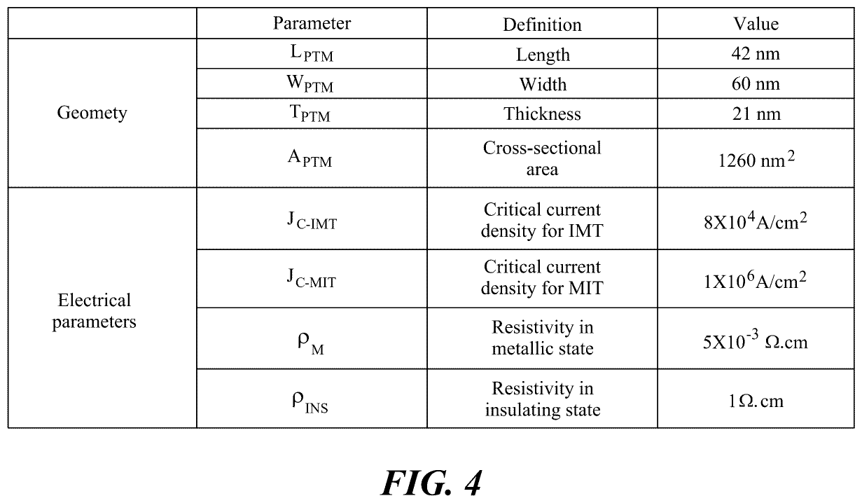

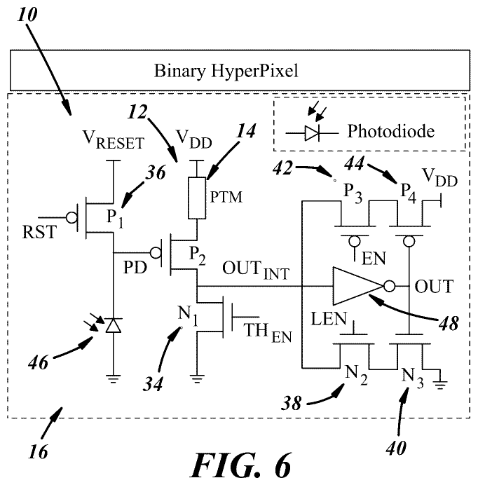

The binary pixel sensor circuit assembly 10 can have various designs, constructions, and components in various embodiments. In the embodiment of FIG. 6, the binary pixel sensor circuit assembly 10 includes the in-pixel binarization module 16. Moreover, the in-pixel binarization module 16 itself can have various designs, constructions, and components in various embodiments. In the embodiment of FIG. 6, the in-pixel binarization module 16 includes a first transistor (PTM & P₂, or the HyperFET 12 with the PTM 14), a second transistor (N₁) 34, a third or reset transistor (P₁) 36, a fourth or latching transistor (N₂) 38, a fifth transistor (N₃) 40, a sixth transistor (P₃) 42, a seventh transistor (P₄) 44, a photodiode 46, and an inverter 48; still, the binary pixel sensor circuit assembly 10 and the in-pixel binarization module 16 could have more, less, and/or different components in different embodiments. The in-pixel binarization module 16 can be divided into three main portions: i) a photodiode (PD) with the reset transistor 36; ii) a thresholding branch (i.e., the HyperFET 12 with the PTM 14, P₂, and second transistor (N₁) 34); and iii) a latch (i.e., the latching transistor (N₂) 38, fifth transistor (N₃) 40, sixth transistor (P₃) 42, and seventh transistor (P₄) 44). Furthermore, fourteen nanometer (14 nm) fin field-effect transistors (FinFET) of the predictive technology model were used to simulate the associated metal-oxide-semiconductor field-effect transistors (MOSFETs) of the binary pixel sensor circuit assembly 10 and the in-pixel binarization module 16. With continued reference to the embodiment of FIG. 6, three gate pulse signals are provided in the binary pixel sensor circuit assembly 10 and the in-pixel binarization module 16: a reset (RST) gate pulse signal, a threshold enable (TH_{EN}) or just threshold gate pulse signal, and a latch enable (LEN) gate pulse signal. A supply voltage V_{DD}=0.7 V is utilized, per an embodiment, in the entire binary pixel sensor circuit assembly 10 and in-pixel binarization module 16. The circuit simulation software known as HSPICE was used to simulate operation of the binary pixel sensor circuit assembly 10 and the in-pixel binarization module 16. Parameters of the PTM 14 that were used in the simulation are presented in the table of FIG. 4; still, other parameters can be used in other simulations, as well as other simulation software, which could yield various results.

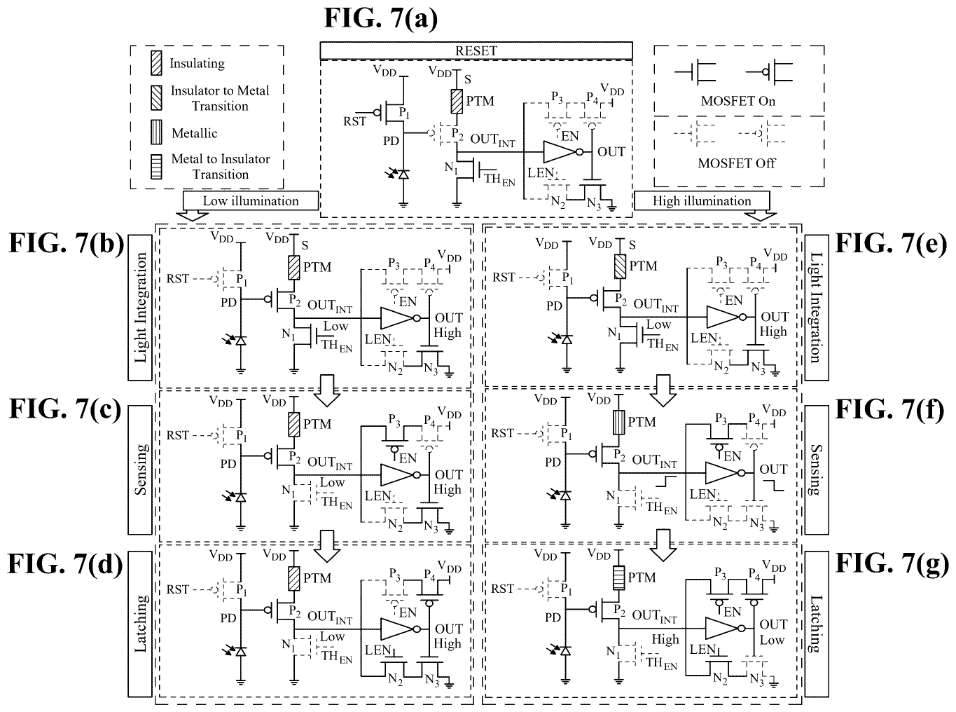

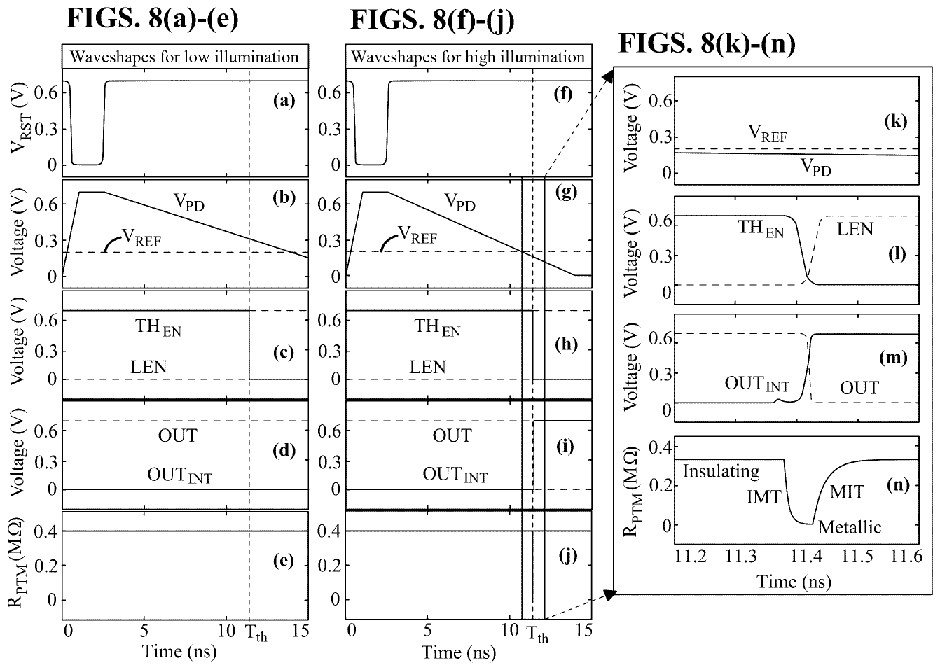

With reference now to FIG. 7, in this embodiment the binary pixel sensor circuit assembly 10 and in-pixel binarization module 16 experience a multitude of operational phases during operation: a reset phase, a light integration phase, a sensing phase, and a latching phase. Based on an incident light, the light integration, sensing, and latching phases can be subject to a low illumination level or a high illumination level. Operation of the binary pixel sensor circuit assembly 10 and in-pixel binarization module 16, per this embodiment, begins with the reset phase (FIG. 7(a)). The reset (RST) gate pulse signal activates the reset transistor (P₁) 36. The photodiode (PD) node charges up to V_{DD} (see FIGS. 8(b) and 8(g)). At the reset phase (FIG. 7(a)), as the associated gate of the P₂ receives a high voltage it is a PMOS in this embodiment the transistor is in its off state and its resistance is high. Between the PTM 14 and P₂, the P₂ receives a higher voltage share according to the voltage divider rule. The PTM 14 does not receive enough voltage for the IMT transition to take place and hence remains in its insulating state. Further, in the subsequent light integration phase of operation of the binary pixel sensor circuit assembly 10 and in-pixel binarization module 16, the reset transistor (P₁) 36 is deactivated and turned off. The voltage at the photodiode (PD) node falls and decreases based at least partly upon an illumination level of the binary pixel sensor circuit assembly 10 and according to equation (1) above. The light integration phase spans up to an integration time period or threshold time period Tₜₕ. In the light integration phase, and per this embodiment, operation of the binary pixel sensor circuit assembly 10 and in-pixel binarization module 16 can advance in one of two trajectories based on an illumination level (i.e., low or high illumination level) of the incident light on the photodiode 46.

When the incident light exhibits the low illumination level, as represented by FIG. 7(b), according to equation (1), a photodiode voltage (V_{PD}) does not decrease enough at or before the integration or threshold time period Tₜₕ (see FIG. 8(b)) and the |V_{GS}| of the HyperFET 12 (PTM 14 & P₂) remains less than |V_{GS-IMT}| (for the HyperFET 12, the photodiode voltage V_{PD} is the gate voltage and a node above the PTM 14 at V_{DD} is the source terminal; a reference voltage V_{REF} is the specific gate voltage of the HyperFET 12 when |V_{GS}|-|V_{GS-IMT}|). Here, the PTM 14 remains in its insulating state. Further, this can be described using a resistance perspective the gate voltage of P₂ is not lowered enough, resulting in a high resistance in P₂, and therefore the PTM 14 does not receive enough voltage share to cross V_{C-IMT} and remains in the insulating state. A voltage at an intermediate output node (OUT_{INT}) is at a low state. Further, in the subsequent sensing phase of operation of the binary pixel sensor circuit assembly 10 and in-pixel binarization module 16, and at the low illumination level (FIG. 7(c) and 8(c)), at the threshold time period Tₜₕ the second transistor (N₁) 34 is deactivated and turned off by lowering the threshold enable (TH_{EN}) gate pulse signal. The binary pixel sensor circuit assembly 10 and in-pixel binarization module 16 is designed and constructed, per this embodiment, in such a way that the combined electrical resistance of P₂ and insulating PTM 14 is much greater than the off resistance of the second transistor (N₁) 34, thus the second transistor (N₁) 34 receives a negligible voltage share, which lets the voltage at the intermediate output node (OUT_{INT}) remain in the low state.

Yet further, in the latching phase of operation of the binary pixel sensor circuit assembly 10 and in-pixel binarization module 16, and at the low illumination level (FIG. 7(d)), the latching transistor (N₂) 38 is turned on by activating the latch enable (LEN) gate pulse signal (FIG. 8(c)). The fifth transistor (N₃) 40 is turned on due to receiving high gate voltage from an output of the inverter 48. Further, a discharging branch consisting of the latching transistor (N₂) 38 and fifth transistor (N₃) 40 is activated, causing discharge of the intermediate output node (OUT_{INT}) and thus receiving logic high state the output of the inverter 48 (FIG. 8(d)). As described, at the low illumination level, the PTM 14 does not switch and the output of the binary pixel sensor circuit assembly 10 and in-pixel binarization module 16 remains unchanged.

When the incident light exhibits the high illumination level, as represented by FIG. 7(e), the photodiode voltage (V_{PD}) falls below and decreases to less than the reference voltage V_{REF} at the threshold time period Tₜₕ (FIG. 8(g)). Here, and in the light integration phase, the |V_{GS}| of the HyperFET 12 begins to cross the |V_{GS-IMT}|, and the PTM 14 begins transitioning from its insulating state to its metal state. This can be described using a resistance perspective the gate voltage of P₂ is lowered enough to turn on this transistor, causing very low electrical resistance at P₂, and therefore the PTM 14 receives enough voltage share to cross V_{C-IMT} and results in the insulator-to-metal transition (IMT). At the last stage of the light integration phase, the PTM 14 becomes fully metallic and is in its metal state. Further, in the subsequent sensing phase of operation of the binary pixel sensor circuit assembly 10 and in-pixel binarization module 16, and at the high illumination level (FIG. 7(f) and 8(h)), the second transistor (N₁) 34 is deactivated and turned off. Here, an upper branch of the intermediate output node (OUT_{INT}) has a turned on transistor (P₂) and a metallic PTM with a very low electrical resistance; conversely, a lower branch of the intermediate output node (OUT_{INT}) has a turned off transistor (N₁) which has a very high electrical resistance. This phenomenon serves to increase the voltage at the intermediate output node (OUT_{INT}) from low to high, and thus the output of the inverter 48 falls and decreases from high to low. It has been observed that as the voltage at the intermediate output node (OUT_{INT}) is becoming high, the voltage across the HyperFET 12 is becoming low, which lowers the voltage across the PTM 14 below and less than V_{C}-MIT, resulting in the metal-to-insulator transition (MIT). But due to the hysteresis property of the PTM 14, it is thought, the V_{C-MIT} is much lower than V_{C-IMT} (see FIG. 3(d)).

Yet further, in the latching phase of operation of the binary pixel sensor circuit assembly 10 and in-pixel binarization module 16, and at the high illumination level (FIG. 7(g)), the latching transistor (N₂) 38 is turned on by activating the latch enable (LEN) gate pulse signal but the fifth transistor (N₃) 40 is turned off as its gate is at the low state, and, in turn, the intermediate output node (OUT_{INT}) is unable to get connected to ground. Conversely, the sixth transistor (P₃) 42 and the seventh transistor (P₄) 44 are turned on, which serve to connect the intermediate output node (OUT_{INT}) to the supply voltage V_{DD}, resulting in the intermediate output node (OUT_{INT}) to be fully charged to a high state and the output of the inverter 48 to become zero (FIG. 8(i)). As described, at the high illumination level, the PTM 14 switches and the output of the binary pixel sensor circuit assembly 10 and in-pixel binarization module 16 changes.

Furthermore, according to an embodiment, the binary pixel sensor circuit assembly 10 and in-pixel binarization module 16 employs the variable thresholding technique and mechanism for effectively discerning scene features across diverse lighting conditions. Variations in imaging conditions occur, for instance, with environments oscillating between excessive brightness and profound darkness. Maintaining a constant threshold in a binary pixel sensor can lead to the generation of identical outputs from all pixels in an array, potentially overlooking important features within an image. The variable thresholding technique and mechanism serves to resolve such issues. The variable thresholding technique and mechanism can take various forms in various embodiments.

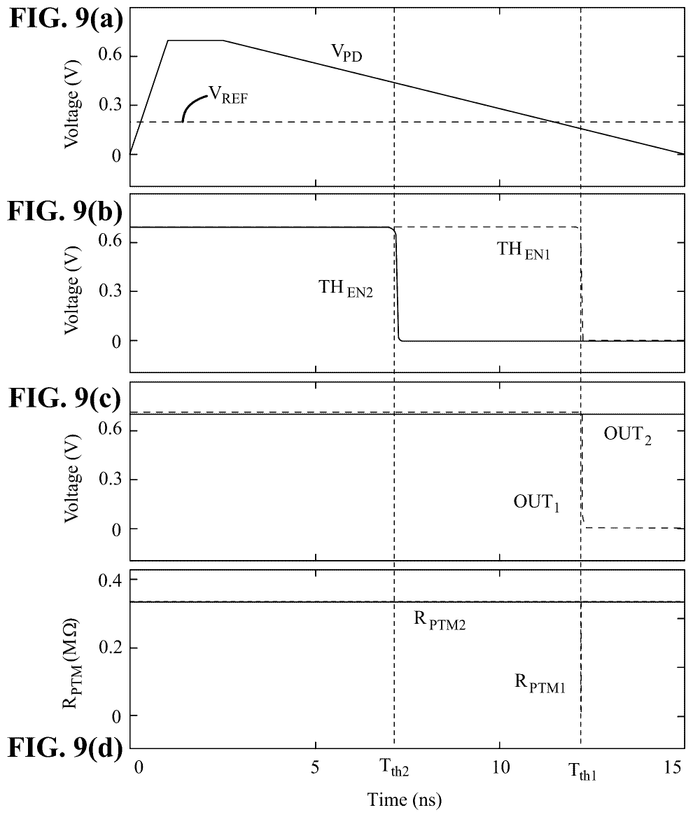

In the embodiment of FIG. 9, the binary pixel sensor circuit assembly 10 and in-pixel binarization module 16 are designed and constructed such that by controlling a pulse width of the threshold enable (TH_{EN}) gate pulse signal, the thresholding decision can be varied. The decaying nature of the voltage at the photodiode (PD) node is exploited with respect to time for the variable thresholding technique and mechanism. As described above, the thresholding decision takes place at the threshold time period Tₜₕ. The pixel voltage can be greater than or less than the reference voltage V_{REF} at the threshold time period Tₜₕ, but before or after the threshold time period Tₜₕ, the opposite can be true. This is because although the reference voltage V_{REF} is constant, the pixel voltage is not. FIG. 9 demonstrates that the reference voltage V_{REF} is fixed and the photodiode voltage (V_{PD}) is falling and decreasing due to illumination.

In a first scenario, the variable thresholding technique and mechanism is activated at a first threshold time period Tₜₕ₁ (FIG. 9(b)) by lowering the threshold enable (TH_{EN}) gate pulse signal (i.e., turning off the second transistor (N₁) 34). At this point in time, V_{PD}<V_{REF}. This treats the incident light as a high illumination level. The PTM 14 switches (FIG. 9(d)) and generates an output accordingly (0 in this example). On the other hand, for the same incident light, in a second scenario, the variable thresholding technique and mechanism is activated at a second threshold time period Tₜₕ₁ (FIG. 9(b)). It is demonstrated in FIG. 9(a) that, at this point in time, V_{PD}>V_{REF}, which is opposite of the first scenario but for the same incident light. This treats the incident light as a low illumination level. The PTM 14 does not switch and an output is generated accordingly (1 in this example). In this way, by varying the thresholding in the time domain, the binary decision can be altered on the basis of the imaging scene conditions. In this embodiment, the reference voltage V_{REF} remains substantially constant and is not varied, and rather the threshold time period Tₜₕ is varied.

Moreover, the reference voltage V_{REF} can be tailored by varying the length and width of the PTM 14. The threshold time period Tₜₕ can be determined dynamically, based upon input light on the whole pixel array 22. For example, if there is too much brightness and almost all of the pixels 18 in the pixel array 22 generate the same output (e.g., 0), this can result in overlooking significant features of scene. To resolve, per an embodiment, the threshold time period Tₜₕ can be lowered, which causes multiple pixels 18 to generate different outputs than in the unaltered threshold time period Tₜₕ; important features previously omitted are now revealed in the scene. The range of variation of the threshold time period Tₜₕ can be theoretically infinite, but larger Tₜₕ may reduce frame rate of the pixel array 22.

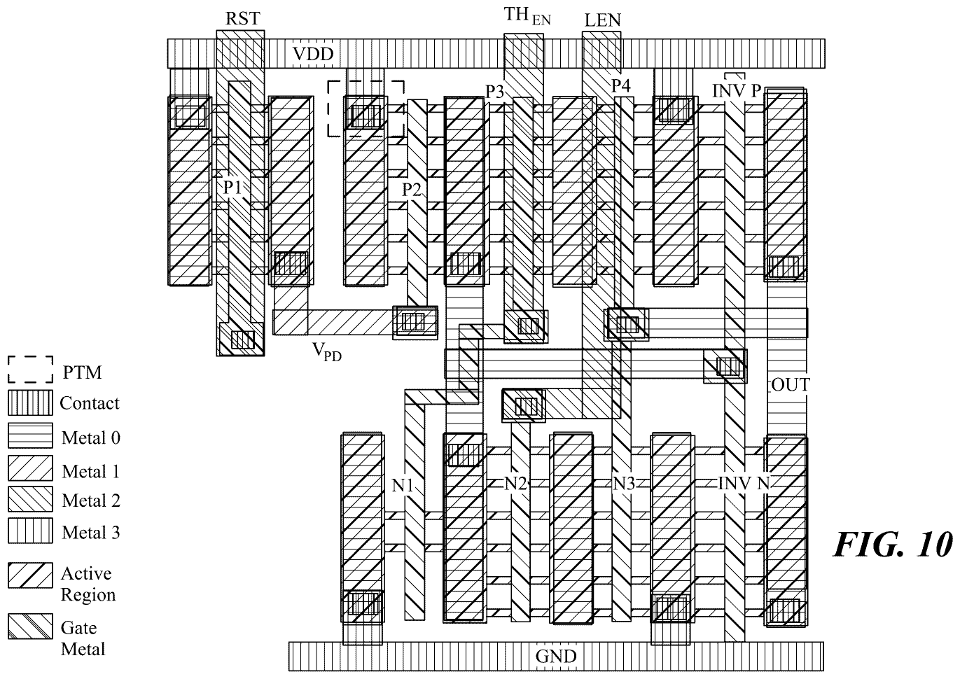

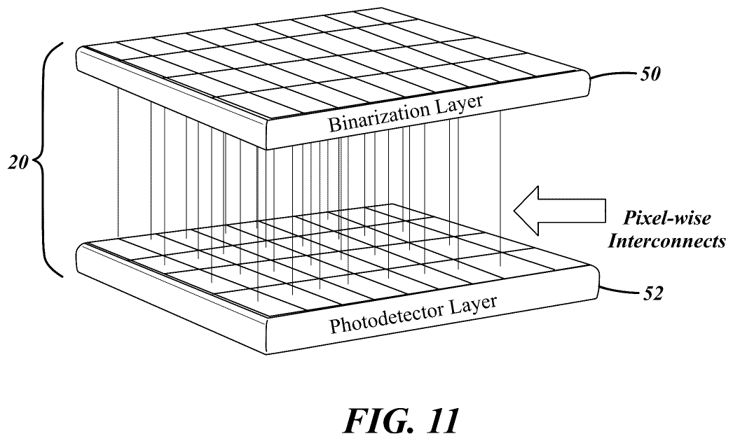

Lastly, with reference now to FIG. 10, a schematic stick diagram of an embodiment of a first layer 50 (e.g., upper or lower layer) of the binary pixel sensor circuit assembly 10 and in-pixel binarization module 16 for an area estimation utilizing fourteen nanometer (14 nm) fin field-effect transistors (FinFET) is presented. The stick diagram of FIG. 10 lacks the photodiode. In an example, the poly pitch and the fin pitch are 70 nm and 42 nm respectively, resulting in an area of 0.35×0.504 m²=0.1764 m² for the binary pixel sensor circuit assembly 10 and in-pixel binarization module 16; still, in other examples other pitches and areas are possible. Further, with reference to FIG. 11, in an embodiment, the image sensor and chip 20 exhibits a stacked configuration with the binary pixel sensor circuit assembly 10 and in-pixel binarization module 16 situated at the first layer 50 (e.g., upper or lower) and a photodiode assembly situated at a second layer 52 (e.g., opposite upper or lower).

In general, while a multitude of embodiments have been depicted and described with a multitude of components and steps in each embodiment, in alternative embodiments the components and steps of various embodiments could be intermixed, combined, and/or exchanged for one another. In other words, components described in connection with a particular embodiment are not necessarily exclusive to that particular embodiment.

As used herein, the terms “general” and “generally” and “substantially” are intended to account for the inherent degree of variance and imprecision that is often attributed to, and often accompanies, any design and manufacturing process, including engineering tolerances and without deviation from the relevant functionality and intended outcome such that mathematical precision and exactitude is not implied and, in some instances, is not possible. In other instances, the terms “general” and “generally” are intended to represent the inherent degree of uncertainty that is often attributed to any quantitative comparison, value, and measurement calculation, or other representation.

It is to be understood that the foregoing is a description of one or more aspects of the disclosure. The disclosure is not limited to the particular embodiment(s) disclosed herein, but rather is defined solely by the claims below. Furthermore, the statements contained in the foregoing description relate to particular embodiments and are not to be construed as limitations on the scope of the disclosure or on the definition of terms used in the claims, except where a term or phrase is expressly defined above. Various other embodiments and various changes and modifications to the disclosed embodiment(s) will become apparent to those skilled in the art. All such other embodiments, changes, and modifications are intended to come within the scope of the appended claims.

As used in this specification and claims, the terms “e.g.,” “for example,” “for instance,” “such as,” and “like,” and the verbs “comprising,” “having,” “including,” and their other verb forms, when used in conjunction with a listing of one or more components or other items, are each to be construed as open-ended, meaning that the listing is not to be considered as excluding other, additional components or items. Other terms are to be construed using their broadest reasonable meaning unless they are used in a context that requires a different interpretation.

What is claimed is:

1. A binary pixel sensor circuit assembly, comprising:
a pixel array comprising a plurality of pixels, at least some of said plurality of pixels having a binarization module residing within said at least some of said plurality of pixels, said binarization module comprising a first transistor and a second transistor electrically coupled with each other, said first transistor being a hybrid phase transition field-effect transistor (HyperFET) having a phase transition material (PTM) at a source terminal thereof.

2. The binary pixel sensor circuit assembly as set forth in claim 1, further comprising a reset transistor electrically coupled with said first transistor, and wherein, during a reset phase amid operation of the binary pixel sensor circuit assembly, a reset gate pulse signal activates said reset transistor and a photodiode voltage of the binary pixel sensor circuit assembly is brought to a supply voltage of the binary pixel sensor, and subsequently said reset transistor is deactivated and said photodiode voltage decreases based at least partly upon an illumination level of the binary pixel sensor circuit assembly, and wherein, during said reset phase, said phase transition material of said hybrid phase transition field-effect transistor remains in an insulating state.

3. The binary pixel sensor circuit assembly as set forth in claim 1, further comprising a reset transistor electrically coupled with said first transistor, and wherein, during a light integration phase amid operation of the binary pixel sensor circuit assembly, said reset transistor is deactivated and, at a low illumination level, a photodiode voltage of the binary pixel sensor circuit assembly remains greater than a reference voltage during an integration time period and said phase transition material of said hybrid phase transition field-effect transistor remains in an insulating state.

4. The binary pixel sensor circuit assembly as set forth in claim 3, wherein, during said light integration phase and at the low illumination level, a voltage at an intermediate output node is at a low state.

5. The binary pixel sensor circuit assembly as set forth in claim 1, further comprising a reset transistor electrically coupled with said first transistor, and wherein, during a light integration phase amid operation of the binary pixel sensor circuit assembly, said reset transistor is deactivated and, at a high illumination level, a photodiode voltage of the binary pixel sensor circuit assembly decreases to less than a reference voltage during an integration time period and said phase transition material of said hybrid phase transition field-effect transistor begins transitioning from an insulating state to a metal state.

6. The binary pixel sensor circuit assembly as set forth in claim 1, wherein, during a sensing phase amid operation of the binary pixel sensor circuit assembly and at a low illumination level, said second transistor is deactivated and said phase transition material of said hybrid phase transition field-effect transistor remains in an insulating state, and a voltage at an intermediate output node remains at a low state.

7. The binary pixel sensor circuit assembly as set forth in claim 6, wherein a first electrical resistance of said first transistor is greater than a second electrical resistance of said second transistor during said sensing phase.

8. The binary pixel sensor circuit assembly as set forth in claim 1, wherein, during a sensing phase amid operation of the binary pixel sensor circuit assembly and at a high illumination level, said second transistor is deactivated and said phase transition material of said hybrid phase transition field-effect transistor is in a metal state and is activated, and a voltage at an intermediate output node is at a high state.

9. The binary pixel sensor circuit assembly as set forth in claim 1, further comprising a latching transistor electrically coupled with said second transistor, and wherein, during a latching phase amid operation of the binary pixel sensor circuit assembly and at a low illumination level, a latch enable gate pulse signal activates said latching transistor, and said phase transition material of said hybrid phase transition field-effect transistor remains in an insulating state and a voltage at an intermediate output node remains at a low state.

10. The binary pixel sensor circuit assembly as set forth in claim 1, further comprising a latching transistor electrically coupled with said second transistor, and wherein, during a latching phase amid operation of the binary pixel sensor circuit assembly and at a high illumination level, a latch enable gate pulse signal activates said latching transistor, and said phase transition material of said hybrid phase transition field-effect transistor transitions from a metal state to an insulating state and a voltage at an intermediate output node is at a high state.

11. The binary pixel sensor circuit assembly as set forth in claim 1, wherein, amid operation of the binary pixel sensor circuit assembly, a pulse width of a threshold gate pulse signal that activates said second transistor is variable while a reference voltage remains substantially constant, the variance of said threshold gate pulse signal is based at least partly upon an illumination level at said plurality of pixels.

12. The binary pixel sensor circuit assembly as set forth in claim 1, wherein, amid operation of the binary pixel sensor circuit assembly, a threshold time period of a threshold gate pulse signal that activates said second transistor is variable with respect to a photodiode voltage of the binary pixel sensor circuit assembly while a reference voltage remains substantially constant, the variance of said threshold time period effecting different outputs of said binarization module for substantially the same illumination level.

13. The binary pixel sensor circuit assembly as set forth in claim 1, wherein all of said plurality of pixels each have a dedicated said binarization module residing therein.

14. An image sensor comprising said binary pixel sensor circuit assembly of claim 1.

15. The image sensor as set forth in claim 14, wherein the image sensor exhibits a stacked configuration with said binary pixel sensor circuit assembly situated at a first layer and a photodiode assembly situated at a second layer.

16. A binary pixel sensor circuit assembly, comprising:
a plurality of pixels, at least some of said plurality of pixels having a binarization module, said binarization module comprising a first transistor and a second transistor, said first transistor being a hybrid phase transition field-effect transistor (HyperFET) having a phase transition material (PTM);
wherein, amid operation of the binary pixel sensor circuit assembly at a low illumination level, said phase transition material of said hybrid phase transition field-effect transistor remains in an insulating state and an output of said binarization module remains unchanged;
wherein, amid operation of the binary pixel sensor circuit assembly at a high illumination level, said phase transition material of said hybrid phase transition field-effect transistor transitions from an insulating state to a metal state and the output of said binarization module changes; and
wherein, amid operation of the binary pixel sensor circuit assembly, a pulse width of a threshold gate pulse signal that activates said second transistor is variable while a reference voltage remains substantially constant.

17. The binary pixel sensor circuit assembly as set forth in claim 16, further comprising a reset transistor and a latching transistor, wherein, during a reset phase amid operation, a reset gate pulse signal activates said reset transistor, wherein, during a light integration phase, said reset transistor is deactivated, wherein, during a sensing phase, said second transistor is deactivated, and wherein, during a latching phase, a latch enable gate pulse signal activates said latching transistor.

18. The binary pixel sensor circuit assembly as set forth in claim 16, wherein, amid operation of the binary pixel sensor circuit assembly, a threshold time period of a threshold gate pulse signal that activates said second transistor is variable with respect to a photodiode voltage of the binary pixel sensor circuit assembly while a reference voltage remains substantially constant.

19. The binary pixel sensor circuit assembly as set forth in claim 16, wherein all of said plurality of pixels each have a dedicated said binarization module residing therein.

20. A binary pixel sensor circuit assembly, comprising:
a pixel array comprising a plurality of pixels, all of said plurality of pixels each having an in-pixel binarization module, said in-pixel binarization module of each of said plurality of pixels comprising a first transistor and a second transistor electrically coupled with each other, said first transistor being a hybrid phase transition field-effect transistor (HyperFET) having a phase transition material (PTM) at a source terminal thereof;
wherein, amid operation of the binary pixel sensor circuit assembly at a low illumination level, said phase transition material of said hybrid phase transition field-effect transistor remains in an insulating state and an output of said in-pixel binarization module remains unchanged;
wherein, amid operation of the binary pixel sensor circuit assembly at a high illumination level, said phase transition material of said hybrid phase transition field-effect transistor transitions from an insulating state to a metal state and the output of said in-pixel binarization module changes; and
wherein, amid operation of the binary pixel sensor circuit assembly, a pulse width of a threshold gate pulse signal that activates said second transistor is variable while a reference voltage remains substantially constant, and a threshold time period of said threshold gate pulse signal is variable with respect to a photodiode voltage of the binary pixel sensor circuit assembly while said reference voltage remains substantially constant.
